(19) United States
(12) Patent Application Publication
(10) Pub. No.: US 2025/0204273 A1
(43) Pub. Date: Jun. 19, 2025

(54) SEMICONDUCTOR MEMORY DEVICE HAVING MAGNETIC CONTROL LAYERS

(71) Applicant: SK hynix Inc., Icheon-si (KR)

(72) Inventors: Jeong Myeong KIM, Icheon-si (KR); Cha Deok DONG, Icheon-si (KR); Keo Rock CHOI, Icheon-si (KR)

(21) Appl. No.: 18/908,615

(22) Filed: Oct. 7, 2024

(30) Foreign Application Priority Data
Dec. 14, 2023 (KR) 10-2023-0181801

(51) Int. Cl. H10N 50/85; H10B 61/00; H10N 50/10

(52) U.S. Cl. CPC H10N 50/85; H10B 61/00; H10N 50/10

(57) ABSTRACT

A semiconductor device includes a lower interconnection line, a lower electrode disposed over the lower interconnection line, a first magnetic control layer disposed over the lower electrode, a selection element layer disposed over the first magnetic control layer, a second magnetic control layer disposed over the selection element layer, a memory element layer disposed over the second magnetic control layer, an upper electrode disposed over the memory element layer, and 10 an upper interconnection line disposed over the upper electrode. Each of the first and second magnetic control layers includes at least one of cobalt, iron, nickel, molybdenum, aluminum, chromium, permalloy, supermalloy, an oxide thereof, or a nitride thereof.

### PRIORITY CLAIM AND CROSS-REFERENCE TO RELATED APPLICATION

This patent document claims the priority and benefits of Korean Patent Application No. 10-2023-0181801 filed on Dec. 14, 2023, which is incorporated herein by reference in its entirety.

### TECHNICAL FIELD

The technology disclosed in this patent document relates to semiconductor memory devices.

### BACKGROUND

Recently, there is a demand for semiconductor devices that can store data in electronic devices such as miniaturized, lower-power, higher-performance computers and portable communication devices. To meet such demands, research is being conducted on semiconductor memory devices that store data using switching property based on voltage or current applied thereto.

### SUMMARY

In an embodiment of the disclosed technology, a semiconductor device includes a lower interconnection line; a lower electrode over the lower interconnection line; a first magnetic control layer over the lower electrode; a selection element layer over the first magnetic control layer; a second magnetic control layer over the selection element layer; a memory element layer over the second magnetic control layer; an upper electrode over the memory element layer; and an upper interconnection line over the upper electrode. In some implementations, the data is read from or written to the memory element layer through the selection element layer configured to exhibit different electrical conducting characteristics in response to an applied voltage with respect to a threshold voltage. In some implementations, the lower and upper interconnection lines are configured to transmit a voltage or current signal in the semiconductor device, and the first and second magnetic control layers are configured to control a magnetic field formed in the selection element layer. Each of the first and second magnetic control layers includes at least one of cobalt, iron, nickel, molybdenum, aluminum, chromium, permalloy, supermalloy, an oxide thereof, or a nitride thereof.

In an embodiment of the disclosed technology, a semiconductor device includes a lower electrode; a first magnetic control layer over the lower electrode; a selection element layer over the first magnetic control layer; a second magnetic control layer over the selection element layer; a magnetic shielding layer over the second magnetic control layer; a memory element layer over the magnetic shielding layer; and an upper electrode over the memory element layer. In some implementations, the data is read from or written to the memory element layer through the selection element layer configured to exhibit different electrical conducting characteristics in response to an applied voltage with respect to a threshold voltage. In some implementations, the first and second magnetic control layers are configured to control a magnetic field formed in the selection element layer. In some implementations, the magnetic shielding layer is configured to reduce the magnetic field to the memory element layer. Each of the first and second magnetic control layers includes a metal without magnetic anisotropy. The magnetic shielding layer includes at least one of a metal alloy layer, an oxide layer, or a nitride layer. Each of the metal alloy layer, the oxide layer, and the nitride layer includes at least two of nickel, iron, copper, aluminum, chromium, or molybdenum.

### BRIEF DESCRIPTION OF THE DRAWINGS

FIG. 1 is a perspective view schematically illustrating a cross-point cell array of a semiconductor memory device based on an embodiment of the disclosed technology.

FIGS. 2A to 2C are longitudinal cross-sectional views taken along the line I-I′ of FIG. 1.

FIGS. 3A to 3C are diagrams illustrating first magnetic control elements based on some embodiments of the disclosed technology.

FIGS. 4A to 4C are diagrams illustrating second magnetic control elements based on some embodiments of the disclosed technology.

FIGS. 5A to 5C are diagrams illustrating adjusting a distance between the first magnetic control element and the second magnetic control element.

FIGS. 6A to 6C are diagrams illustrating a first magnetic shielding element based on some embodiments of the disclosed technology.

FIGS. 7A to 7C are diagrams illustrating a second magnetic shielding element based on some embodiments of the disclosed technology.

FIG. 8 is a diagram illustrating a memory element layer based on an embodiment of the disclosed technology.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

The disclosed technology can be implemented in some embodiments to provide a cross-point semiconductor memory device having magnetic control layers.

The disclosed technology can be implemented in some embodiments to offset an eddy current that may be generated by electromagnetic induction and to reduce a leakage current in a selection element layer.

The disclosed technology can be implemented in some embodiments to provide a cross-point semiconductor memory device having a magnetic shielding layer.

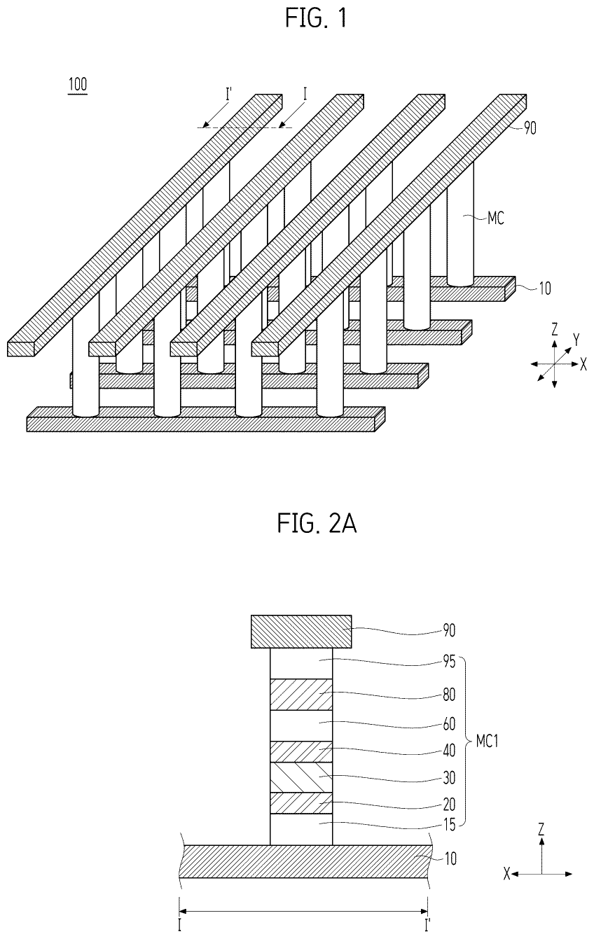

FIG. 1 is a perspective view schematically illustrating a cross-point cell array 100 of a semiconductor memory device based on an embodiment of the disclosed technology.

Referring to FIG. 1, the cross-point cell array 100 of the semiconductor memory device based on an embodiment of the disclosed technology may include lower interconnection lines 10, upper interconnection lines 90, and memory cell structures MC. In some implementations, the term “interconnection line” can be used to indicate a transmission line that can be used to transmit electrical signals between different regions in the semiconductor memory device. The lower interconnection lines 10 may extend in parallel with each other in a first horizontal direction X. The upper interconnection lines 90 may extend in parallel with each other in a second horizontal direction Y. The first horizontal direction X and the second horizontal direction Y may be perpendicular to each other. The memory cell structures MC may be disposed at intersections between the lower interconnection lines 10 and the upper interconnection lines 90. Each of the memory cell structures MC may have a cylindrical pillar shape.

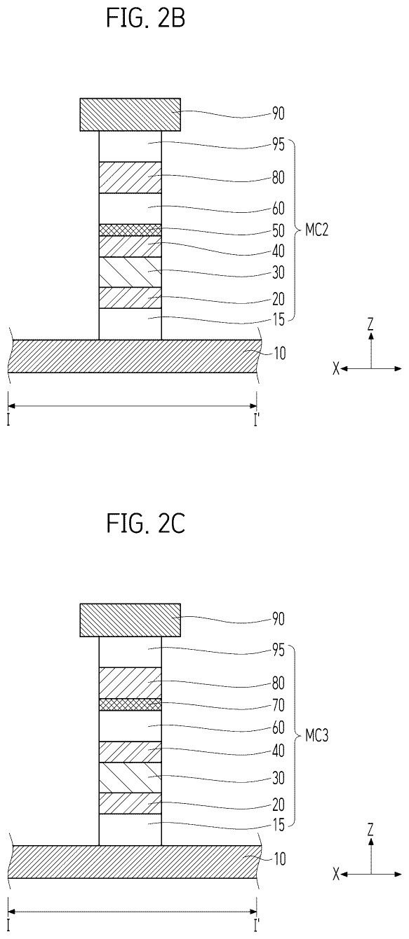

FIG. 2A to 2C are longitudinal cross-sectional views taken along the line I-I′ of FIG. 1. Referring to FIG. 2A to 2C, the cross-point cell arrays 100 of a semiconductor memory device based on some embodiments of the disclosed technology may include memory cell structures MC1 to MC3 disposed between a lower interconnection line 10 and an upper interconnection line 90, respectively. The lower interconnection line 10 may be disposed on a substrate or a lower insulating layer. The lower interconnection line 10 may have a line shape extending in the first horizontal direction X. The lower interconnection line 10 may include a conductor e.g., a metal, a metal silicide, a metal compound, or a metal alloy. For example, the lower interconnection line 10 may include at least one of tungsten (W), titanium (Ti), tantalum (Ta), platinum (Pt), aluminum (Al), copper (Cu), zinc (Zn), nickel (Ni), cobalt (Co), lead (Pd), chromium (Cr), tungsten nitride (WN), tungsten silicide (WSi), titanium silicide (TiSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), titanium aluminum (TiAl), or combinations thereof. The upper interconnection line 90 may be disposed on the memory cell structures MC1-MC3, respectively. Referring to FIG. 1, the upper interconnection line 90 may have a line shape extending in the second horizontal direction Y. The upper interconnection line 90 may include a conductor e.g., a metal, a metal silicide, a metal compound, or a metal alloy.

Referring to FIG. 2A, the memory cell structure MC1 of the semiconductor memory device based on an embodiment of the disclosed technology may include a lower electrode 15, a first magnetic control element 20, a selection element layer 30, a second magnetic control element 40, a middle electrode 60, a memory element layer 80, and an upper electrode 95 stacked in a vertical direction Z between the lower interconnection line 10 and the upper interconnection line 90. The lower electrode 15, the first magnetic control element 20, the selection element layer 30, the second magnetic control element 40, the middle electrode 60, the memory element layer 80, and the upper electrode 95 may have a pillar shape or a pad shape, respectively.

The lower electrode 15 may be directly disposed on the lower interconnection line 10. The lower electrode 15 may receive a voltage or current from the lower interconnection line 10 and transmit or provide the voltage or current to the selection element layer 30. The lower electrode 15 may include a conductor e.g., a metal, a metal silicide, a metal compound, or a metal alloy. For example, the lower electrode 15 may include at least one of tungsten (W), titanium (Ti), tantalum (Ta), platinum (Pt), aluminum (AI), copper (Cu), zinc (Zn), nickel (Ni), cobalt (Co), chromium (Cr), tungsten nitride (WN), tungsten silicide (WSi), titanium silicide (TiSi), titanium nitride (TiN), titanium silicon nitride (TiN), titanium aluminum nitride (TiAlN), tantalum nitride (TaN), tantalum silicon nitride (TaSiN), tantalum aluminum nitride (TaAlN), titanium aluminum (TiAl), or combinations thereof.

The first magnetic control element 20 and the second magnetic control element 40 may control a magnetic field formed in the selection element layer 30 to maintain the magnetic field at a uniform level by attenuating the electromagnetic field by channel formation. Therefore, after the channel formation in the selection element layer 30, the generated hysteresis loss can be countervailed and a leakage current can be reduced.

The selection element layer 30 may be disposed on the lower electrode 15. In some implementations, the selection element layer 30 may exhibit different electrical conducting characteristics or states in response to an applied voltage or current with respect to a threshold voltage or current. For example, the selection element layer 30 may exhibit different states of its electrical conductivity when subject to an electric field generated between the lower electrode 15 and the middle electrode 60. That is, a conductive channel may be formed in the selection element layer 30 under the control of the electric filed generated between the lower electrode 15 and the middle electrode 60. When the voltage associated with the electric field is less than a threshold voltage or the current associated with the electric field is less than a threshold current, the selection element layer 30 may exhibit a non-conductive property to cut off a current path through the selection element layer 30 to the memory element layer 80. When the voltage associated with the electric field is greater than or equal to the threshold voltage or the current associated with the electric field is greater than the threshold current, the selection element layer 30 may exhibit conductive property by forming a conductive channel or the current path to the memory element layer 80. In an embodiment, the selection element layer 30 may include an ion-doped insulating layer. For example, the selection element layer 30 may include ion-doped silicon oxide, ion-doped titanium oxide, ion-doped aluminum oxide, ion-doped tungsten oxide, ion-doped hafnium oxide, ion-doped tantalum oxide, ion-doped niobium oxide, ion-doped silicon nitride, ion-doped titanium nitride, ion-doped aluminum nitride, ion-doped tungsten nitride, ion-doped hafnium nitride, ion-doped tantalum nitride, ion-doped niobium nitride, ion-doped silicon oxynitride, ion-doped titanium oxynitride, ion-doped aluminum oxynitride, ion-doped tungsten oxynitride, ion-doped hafnium oxynitride, ion-doped tantalum oxynitride, ion-doped niobium oxynitride, or combinations thereof. The ions may include at least one of arsenic (As) or germanium (Ge). For example, the selection element layer 30 may include a silicon oxide layer doped with at least one of arsenic (As) or germanium (Ge) (e.g., As-SiO₂, Ge-SiO₂, and AsGe-SiO₂).

The middle electrode 60 may be disposed on the selection

element layer 30 or the second magnetic control element 40. The middle electrode 60 may include a carbon layer. In an embodiment, the middle electrode 60 may include at least one of conductors, e.g., a metal containing carbon, a metal compound containing carbon, a metal alloy containing carbon, or a metal silicide containing carbon. In another embodiment, the middle electrode 60 may include a carbon structure layer, e.g., graphene layers.

The memory element layer 80 may be disposed on the middle electrode 60. The memory element layer 80 may include a variable resistance layer. For example, the memory element layer 80 may include a magnetic resistance layer or a phase-changeable resistance layer. In an embodiment, the memory element layer 80 may include a magnetic tunnel junction (MTJ).

The upper electrode 95 may be disposed on the memory element layer 80. The upper electrode 95 may transmit and provide the current passed through the memory element layer 80 to the upper interconnection line 90. The upper electrode 95 may include a conductor, e.g., a metal, a metal silicide, a metal compound, or a metal alloy. For example, the upper electrode 95 may include at least one of tungsten (W), titanium (Ti), tantalum (Ta), platinum (Pt), aluminum (Al), copper (Cu), zinc (Zn), nickel (Ni), cobalt (Co), chromium (Cr), tungsten nitride (WN), tungsten silicide (WSi), titanium silicide (TiSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), titanium aluminum (TiAl), or a combination thereof.

Referring to FIG. 2B, a memory cell structure MC2 of a semiconductor memory device based on an embodiment of the disclosed technology may include a lower electrode 15, a first magnetic control element 20, a selection element layer 30, a second magnetic control element 40, a first magnetic shielding element 50, a middle electrode 60, a memory element layer 80, and an upper electrode 95 stacked in the vertical direction Z between the lower interconnection line 10 and the upper interconnection line 90. Compared with the memory cell structure MC1 of FIG. 2A, the memory cell structure MC2 may further include the first magnetic shielding element 50 disposed between the second magnetic control element 40 and the middle electrode 60.

Referring to FIG. 2C, a memory cell structure MC3 of a semiconductor memory device based on an embodiment of the disclosed technology may include a lower electrode 15, a first magnetic control element 20, a selection element layer 30, a second magnetic control element 40, a middle electrode 60, a second magnetic shielding element 70, a memory element layer 80, and an upper electrode 95 stacked in the vertical direction Z between the lower interconnection line 10 and the upper interconnection line 90. Different from the memory cell structure MC1 of FIG. 2A, the memory cell structure MC3 may further include the second magnetic shielding element 70 disposed between the middle electrode 60 and the memory element layer 80.

The first and second magnetic shielding elements 50 and 70 may be selectively disposed on a lower portion or an upper portion of the middle electrode 60, respectively. The first and second magnetic shielding elements 50 and 70 may shield or reduce influence of a magnetic field on the memory element layer 80.

In some embodiments, the memory cell structures MC1-MC3 may be implemented without the lower electrode 15 and the upper electrode 95. For example, an element (e.g., the lower interconnection line 10) under the lower electrode 15 and an element (e.g., the first magnetic control element 20) over the lower electrode 15 may be connected to or directly in contact with each other, and an element (e.g., the memory element layer 80) under the upper electrode 95 and an element (e.g., the upper interconnection line) over the upper electrode 95 may be directly in contact with each other.

In some embodiments, the memory cell structures MC1-MC3 may be implemented without at least one of the first magnetic control element 20, the second magnetic control element 40, or the first and second magnetic shielding elements 50 and 70.

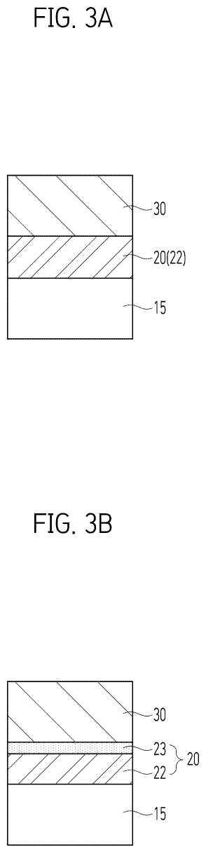

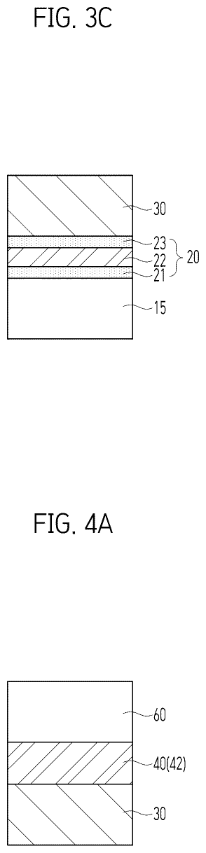

FIGS. 3A to 3C are diagrams illustrating first magnetic control elements 20 based on some embodiments of the disclosed technology.

Referring to FIG. 3A, a first magnetic control element 20 based on an embodiment of the disclosed technology may include a first magnetic control layer 22. For example, the first magnetic control element 20 may indicate the same layer as the first magnetic control layer 22. The first magnetic control layer 22 may be directly in contact with the lower electrode 15 and the selection element layer 30.

Referring to FIG. 3B, a first magnetic control element 20 based on an embodiment of the disclosed technology may include a first magnetic control layer 22 and a first upper magnetic control barrier layer 23. For example, the first upper magnetic control barrier layer 23 may be disposed between the first magnetic control layer 22 and the selection element layer 30. The first upper magnetic control barrier layer 23 may block diffusion and movement of atoms between the first magnetic control layer 22 and the selection element layer 30. The first upper magnetic control barrier layer 23 may reinforce adhesion between the first magnetic control layer 22 and the selection element layer 30.

Referring to FIG. 3C, a first magnetic control element 20 based on an embodiment of the disclosed technology may include a first lower magnetic control barrier layer 21, a first magnetic control barrier layer 22, and a first upper magnetic control barrier layer 23. The first lower magnetic control barrier layer 21 may be disposed between the lower electrode 15 and the first magnetic control layer 22. The first lower magnetic control barrier layer 21 may block diffusion and movement of atoms between the lower electrode 15 and the first magnetic control layer 22. The first lower magnetic control barrier layer 21 may reinforce adhesion between the lower electrode 15 and the first magnetic control layer 22.

The first lower magnetic control barrier layer 21 and the first upper magnetic control barrier layer 21 may include a conductor, e.g., a metal, a metal silicide, a metal compound, or a metal alloy. In an embodiment, the first lower magnetic control barrier layer 21 and the first upper magnetic control barrier layer 23 may include at least one of titanium nitride (TiN), titanium tungsten (TiW), or titanium aluminum nitride (TiAlN).

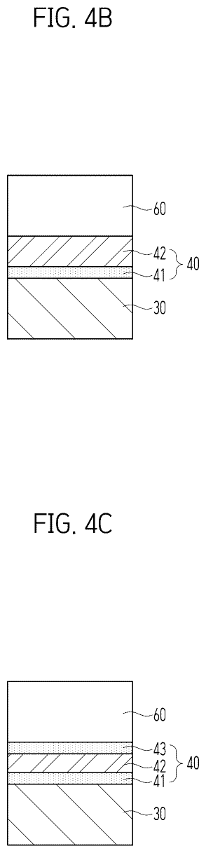

FIGS. 4A to 4C are diagrams illustrating second magnetic control elements 40 based on some embodiments of the disclosed technology.

Referring to FIG. 4A, a second magnetic control element 40 based on an embodiment of the disclosed technology may include a second magnetic control layer 42. For example, the second magnetic control element 40 may be the second magnetic control layer 42. The second magnetic control layer 42 may be directly in contact with the selection element layer 30 and the middle electrode 60.

Referring to FIG. 4B, a second magnetic control element 40 based on an embodiment of the disclosed technology may include a second lower magnetic control barrier layer 41 and a second magnetic control layer 42. For example, the second lower magnetic control barrier layer 41 may be disposed between the selection element layer 30 and the second magnetic control layer 42. The second lower magnetic control barrier layer 41 may block diffusion and movement of atoms between the selection element layer 30 and the second magnetic control layer 42. The second lower magnetic control barrier layer 41 may reinforce adhesion between the selection element layer 30 and the second magnetic control layer 42.

Referring to FIG. 4C, a second magnetic control element 40

based on an embodiment of the disclosed technology may include a second lower magnetic control barrier layer 41, a second magnetic control layer 42, and a second upper magnetic control barrier layer 43. The second upper magnetic control barrier layer 43 may be disposed between the second magnetic control layer 42 and the middle electrode 60. The second upper magnetic control barrier layer 43 may block diffusion and movement of atoms between the second magnetic control layer 42 and the middle electrode 60. The second upper magnetic control barrier layer 43 may reinforce adhesion between the second magnetic control layer 42 and the middle electrode 60.

The second lower magnetic control barrier layer 41 and the second upper magnetic control barrier layer 43 may include a conductor, e.g., a metal, a metal silicide, a metal compound, or a metal alloy. In an embodiment, the second lower magnetic control barrier layer 41 and the second upper magnetic control barrier layer 43 may include at least one of titanium nitride (TiN) or titanium aluminum nitride (TiAlN).

The first magnetic control layer 22 and the second magnetic control layer 42 may include materials without magnetic anisotropy. For example, each of the first magnetic control layer 22 and the second magnetic control layer 42 may include at least one of cobalt (Co), iron (Fe), nickel (Ni), molybdenum (Mo), aluminum (Al), chromium (Cr), permalloy, or supermalloy. In one embodiment, each of the first magnetic control layer 22 and the second magnetic control layer 42 may include one of oxides including at least one of cobalt (Co), iron (Fe), nickel (Ni), molybdenum (Mo), aluminum (Al), chromium (Cr), permalloy, or supermalloy. In an embodiment, each of the first magnetic control layer 22 and the second magnetic control layer 42 may include one of nitrides including at least one of cobalt (Co), iron (Fe), nickel (Ni), molybdenum (Mo), aluminum (Al), chromium (Cr), permalloy, or supermalloy. The permalloy may include nickel (Ni) and iron (Fe). For example, the permalloy may contain about 80% of nickel (Ni) and about 20% of iron (Fe). The supermalloy may include nickel (Ni), iron (Fe), and molybdenum (Mo). For example, the supermalloy may include about 75% of nickel (Ni), about 20% of iron (Fe), and about 5% of molybdenum (Mo).

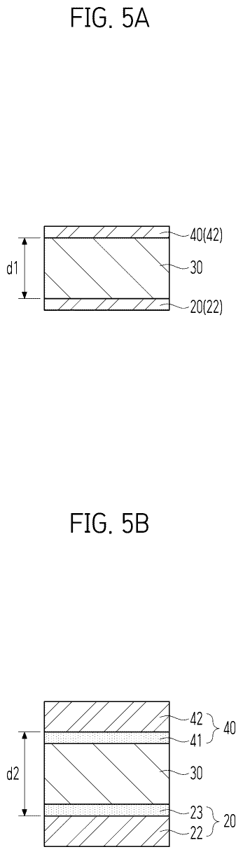

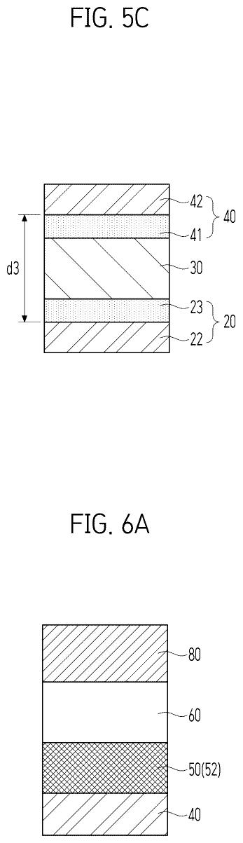

FIGS. 5A to 5C are diagrams illustrating adjusting a distance between the first magnetic control element 20 and the second magnetic control element 40. Referring to FIG. 5A, a distance (gap) between the first magnetic control layer 22 of first magnetic control element 20 and the second magnetic control layer 42 of the second magnetic control element 40 may be a first distance d1. As shown in FIGS. 3A and 4A, the first magnetic control layer 22 of the first magnetic control element 20 and the second magnetic control layer 42 of the second magnetic control element 40 may directly in contact with the selection element layer 30.

Referring to FIG. 5B, a distance (gap) between the first magnetic control layer 22 of the first magnetic control element 20 and the second magnetic control layer 42 of the second magnetic control element 40 may be a second distance d2. As shown in FIGS. 3B and 4B, the first upper magnetic control barrier layer 23 may be disposed between the selection element layer 30 and the first magnetic control layer 22, and the second lower magnetic control barrier layer 41 may be disposed between the selection element layer 30 and the second magnetic control layer 42. The distance (gap) between the first magnetic control layer 22 and the second magnetic control layer 42 may be adjusted by the first upper magnetic control barrier layer 23 and the second lower magnetic control barrier layer 41. That is, as compared with FIG. 5A, the distance (gap) between the first magnetic control layer 22 and the second magnetic control layer 42 may be increased. As shown in the drawing, the second distance d2 may be greater than the first distance d1.

Referring to FIG. 5C, as compared with FIG. 5B, thicknesses of the first upper magnetic control barrier layer 23 and the second lower magnetic control barrier layer 41 may be increased. Accordingly, the distance (gap) between the first magnetic control layer 22 of the first magnetic control element 20 and the second magnetic control layer 42 of the second magnetic control element 40 may be a third distance d3. The third distance d3 may be greater than the second distance d2.

Referring to FIGS. 5A to 5C, the distance between the first magnetic control layer 22 and the second magnetic control layer 42 may be adjusted by the thicknesses of the first upper magnetic control barrier layer 23 and the second lower magnetic control barrier layer 41. The first upper magnetic control barrier layer 23 and the second lower magnetic control barrier layer 41 may be disposed or omitted independently. For example, only one of the first upper magnetic control barrier layer 23 and the second lower magnetic control barrier layer 41 may be selectively disposed.

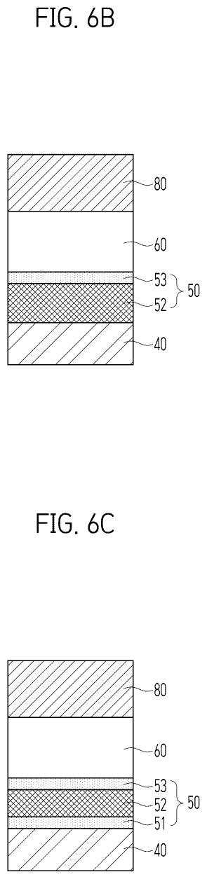

FIGS. 6A to 6C are diagrams illustrating a first magnetic shielding element 50 based on some embodiments of the disclosed technology. Referring to FIG. 6A, a first magnetic shielding element 50 based on an embodiment of the disclosed technology may be disposed between the second magnetic control element 40 and the middle electrode 60. The first magnetic shielding element 50 may include a first magnetic shielding layer 52. For example, the first magnetic shielding element 50 may be the same as the first magnetic shielding layer 52. The first magnetic shielding layer 52 may be directly in contact with the second magnetic control element 40 and the middle electrode 60.

Referring to FIG. 6B, a first magnetic shielding element 50 based on an embodiment of the disclosed technology may include a first magnetic shielding layer 52 and a first upper magnetic shielding barrier layer 53. The first upper magnetic shielding barrier layer 53 may be disposed between the first magnetic shielding layer 52 and the middle electrode 60. The first upper magnetic shielding barrier layer 53 may block diffusion and movement of atoms between the first magnetic shielding layer 52 and the middle electrode 60. The first upper magnetic shielding barrier layer 53 may reinforce adhesion between the first magnetic shielding layer 52 and the middle electrode 60.

Referring to FIG. 6C, a first magnetic shielding element 50 based on an embodiment of the disclosed technology may include a first lower magnetic shielding barrier layer 51, a first magnetic shielding layer 52, and a first upper magnetic shielding barrier layer 53. The first lower magnetic shielding barrier layer 51 may be disposed between the second magnetic element 40 and the magnetic shielding layer 52. The first lower magnetic shielding barrier layer 51 may block diffusion and movement of atoms between the second magnetic element 40 and the first magnetic shielding layer 52. The first lower magnetic shielding barrier layer 51 may reinforce adhesion between the second magnetic element 40 and the first magnetic shielding layer 52. In FIG. 6C, the first upper magnetic shielding barrier layer 53 may be omitted.

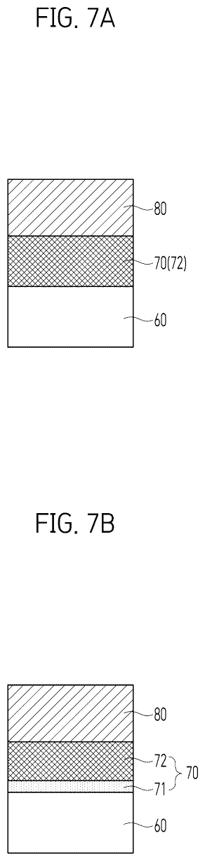

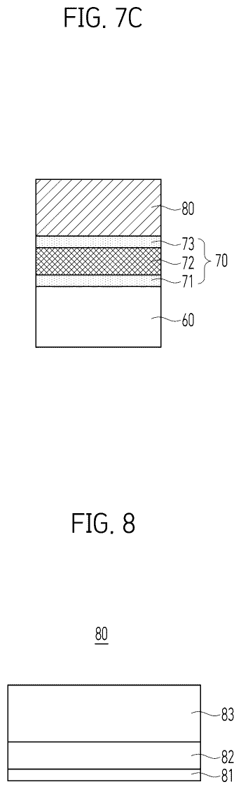

FIGS. 7A to 7C are diagrams illustrating a second magnetic shielding element 70 based on some embodiments of the disclosed technology. Referring to FIG. 7A, a second magnetic shielding element 70 based on an embodiment of the disclosed technology may be disposed between the middle electrode 60 and the memory element layer 80. The second magnetic shielding element 70 may include a second magnetic shielding layer 72. For example, the second magnetic shielding element 70 may be the same as the second magnetic shielding layer 72. The second magnetic shielding layer 72 may be directly in contact with the middle electrode 60 and the memory element layer 80.

Referring to FIG. 7B, a second magnetic shielding element 70 based on an embodiment of the disclosed technology may include a second lower magnetic shielding barrier layer 71 and a second magnetic shielding layer 72. The second lower magnetic shielding barrier layer 71 may be disposed between the middle electrode 60 and the second magnetic shielding layer 72. The second lower magnetic shielding barrier layer 71 may block diffusion and movement of atoms between the middle electrode 60 and the second magnetic shielding layer 72. The second lower magnetic shielding barrier layer 71 may reinforce adhesion between the middle electrode 60 and the second magnetic shielding layer 72.

Referring to FIG. 7C, a second magnetic shielding element 70 based on an embodiment of the disclosed technology may include a second lower magnetic shielding barrier layer 71, a second magnetic shielding layer 72, and a second upper magnetic shielding barrier layer 73. The second upper magnetic shielding barrier layer 73 may be disposed between the second magnetic shielding layer 72 and the memory element layer 80. The second upper magnetic shielding barrier layer 73 may block diffusion and movement of atoms between the second magnetic shielding layer 72 and the memory element layer 80. The second upper magnetic shielding barrier layer 73 may reinforce adhesion between the second magnetic shielding layer 72 and the memory element layer 80. In FIG. 6C, the second lower magnetic shielding barrier layer 71 may be omitted.

In an embodiment, each of the first and second magnetic shielding layers 52 and 72 may include a metal alloy including at least two of nickel (Ni), iron (Fe), copper (Cu), aluminum (Al), chromium (Cr), and molybdenum (Mo). In an embodiment, each of the first and second magnetic shielding layers 52 and 72 may include at least one of ferrite, permalloy, supermalloy, carbon steel, stainless steel, an Ni-Co based material, an Fe-Ni based material, an Fe-Cr based material, an Fe-Al based material, an Fe-Si-B based material, an Fe-Si-B-Cu-Nb based material, an Mn-Zn based material, an Ni-Zn based material, an Ni-Co based material, an Mg-Zn based material, or a Cu-Zn based material. In an embodiment, each of the first and second magnetic shielding elements 50 and 70 may include about 70% to 80% of nickel (Ni), about 15% to 25% of iron (Fe), and about 5% of at least one of copper (Cu), aluminum (Al), chromium (Cr), or molybdenum (Mo).

The first and second lower magnetic shielding barrier layers 51 and 71, and the first and second upper magnetic shielding barrier layers 53 and 73 may each include a conductor, e.g., a metal, a metal silicide, a metal compound, or a metal alloy. In an embodiment, the first and second lower magnetic shielding barrier layers 51 and 71 and the first and second upper magnetic shielding barrier layers 53 and 73 may each include at least one of titanium nitride (TiN), titanium tungsten (TiW), or titanium aluminum nitride (TiAlN).

The first and second magnetic shielding elements 50 and 70 may be exclusively disposed. That is, any one of the first and second magnetic shielding elements 50 and 70 may be selectively disposed or omitted.

FIG. 8 is a diagram illustrating a memory element layer 80 based on an embodiment of the disclosed technology. Referring to FIG. 8, the memory element layer 80 based on an embodiment of the disclosed technology may include a magnetic tunnel function (MTJ). For example, the memory element layer 80 may include a lower magnetic layer 81, a tunneling barrier layer 82, and an upper magnetic layer 83. In an embodiment, the lower magnetic layer 81 may be a free magnetization layer, and the upper magnetic layer 83 may be a fixed (pinned) magnetization layer. In another embodiment, the lower magnetic layer 81 may be a fixed (pinned) magnetization layer, and the upper magnetic layer 83 may be a free magnetization layer. The lower magnetic layer 81 and the upper magnetic layer 83 may include an alloy or compound including at least two of iron (Fe), nickel (Ni), cobalt (Co), boron (B), platinum (Pt), and palladium (Pd). For example, the first magnetic layer 81 may include at least one of an Fe-Pt alloy, an Fe-Pd alloy, a Co-Pd alloy, a Co-Pt alloy, a Fe-Ni-Pt alloy, a Co-Fe-Pt alloy, a Co-Fe-B alloy, a Co/Pt stack, or a Co/Pd stack, respectively.

The tunneling barrier layer 82 may be disposed between the lower magnetic layer 81 and the upper magnetic layer 83. Electrons may tunnel the tunneling barrier layer 82 by an electric field between the lower electrodes 15 and the upper electrodes 95. The tunneling barrier layer 82 may include an insulating metal oxide. For example, the tunneling barrier layer 82 may include at least one of a magnesium oxide (MgO) layer, a calcium oxide (CaO) layer, a strontium oxide (SrO) layer, a titanium oxide (TiO) layer, a vanadium oxide (Vo) layer, a niobium oxide (NbO) layer, an aluminum oxide (AlO) layer, a tantalum oxide (TaO) layer, a ruthenium oxide (RuO) layer, a beryllium oxide (BeO) layer, a barium oxide (BaO) layer, or a bismuth oxide (BiO) layer.

In some embodiments of the disclosed technology, leakage current generated after channel formation can be reduced.

In some embodiments of the disclosed technology, leakage current in the off state can be reduced.

In some embodiments of the disclosed technology, a uniform electromagnetic field can be formed in the selection element layer.

Only a few embodiments and examples are described. Enhancements and variations of the disclosed embodiments and other embodiments can be made based on what is described and illustrated in this patent document.

What is claimed is:

1. A semiconductor device comprising:
a lower interconnection line;
a lower electrode disposed over the lower interconnection line;
a first magnetic control layer disposed over the lower electrode;
a selection element layer disposed over the first magnetic control layer;
a second magnetic control layer disposed over the selection element layer, wherein the first and second magnetic control layers are configured to control a magnetic field in the selection element layer;
a memory element layer disposed over the second magnetic control layer and configured to store data;
an upper electrode disposed over the memory element layer; and
an upper interconnection line disposed over the upper electrode,
wherein each of the first and second magnetic control layers includes at least one of cobalt, iron, nickel, molybdenum, aluminum, chromium, permalloy, supermalloy, an oxide of one or more of cobalt, iron, nickel, molybdenum, aluminum, chromium, permalloy, supermalloy, or a nitride of one or more of cobalt, iron, nickel, molybdenum, aluminum, chromium, permalloy, supermalloy.

2. The semiconductor device of claim 1, further comprising:
a first upper magnetic control barrier layer disposed between the first magnetic control layer and the selection element layer.

3. The semiconductor device of claim 2,
wherein the first upper magnetic control barrier layer includes titanium nitride.

4. The semiconductor device of claim 1, further comprising:
a first lower magnetic barrier layer disposed between the lower electrode and the first magnetic control layer.

5. The semiconductor device of claim 1, further comprising:
a lower magnetic barrier layer disposed between the selection element layer and the second magnetic control layer.

6. The semiconductor device of claim 5,
wherein the lower magnetic barrier layer includes titanium nitride.

7. The semiconductor device of claim 5, further comprising:
an upper magnetic barrier layer disposed between the second magnetic control layer and the memory element layer.

8. The semiconductor device of claim 1, further comprising:
a middle electrode disposed between the second magnetic control layer and the memory element layer.

9. The semiconductor device of claim 8,
Wherein the middle electrode includes at least one of a carbon layer, a metal containing carbon, a metal compound containing carbon, a metal alloy containing carbon, a metal silicide containing carbon, or a graphene layer.

10. The semiconductor device of claim 8, further comprising:
a magnetic shielding layer disposed between the second magnetic control layer and the middle electrode or between the middle electrode and the memory element layer.

11. The semiconductor device of claim 10,
wherein the magnetic shielding layer includes a metal alloy including at least two of nickel, iron, copper, aluminum, chromium, or molybdenum.

12. The semiconductor device of claim 10, further comprising:
a magnetic shielding barrier layer disposed between the magnetic shielding layer and the middle electrode.

13. The semiconductor device of claim 12,
wherein the magnetic shielding barrier layer includes titanium nitride.

14. The semiconductor device of claim 10, further comprising:
a magnetic shielding barrier layer disposed between the magnetic shielding layer and the memory element layer.

15. A semiconductor device comprising:
a lower electrode;
a first magnetic control layer disposed over the lower electrode;
a selection element layer disposed over the first magnetic control layer;
a second magnetic control layer disposed over the selection element layer;
a magnetic shielding layer disposed over the second magnetic control layer;
a memory element layer disposed over the magnetic shielding layer and configured to store data; and
an upper electrode disposed over the memory element layer,
wherein the first and second magnetic control layers are configured to control a magnetic field formed in the selection element layer, and the magnetic shielding layer is configured to reduce the magnetic field to the memory element layer,
wherein each of the first and second magnetic control layers includes a metal without magnetic anisotropy,
wherein the magnetic shielding layer includes at least one of a metal alloy layer, an oxide layer, or a nitride layer,
wherein each of the metal alloy layer, the oxide layer, and the nitride layer includes at least two of nickel, iron, copper, aluminum, chromium, or molybdenum.

16. The semiconductor device of claim 15,
wherein each of the first and second magnetic control layers includes at least one of cobalt, iron, nickel, molybdenum, aluminum, chromium, permalloy, supermalloy, an oxide of one or more of cobalt, iron, nickel, molybdenum, aluminum, chromium, permalloy, supermalloy, or a nitride of one or more of cobalt, iron, nickel, molybdenum, aluminum, chromium, permalloy, supermalloy.

17. The semiconductor device of claim 15, further comprising:
a middle electrode disposed between the second magnetic control layer and the magnetic shielding layer or between the magnetic shielding layer and the memory element layer.

18. The semiconductor device of claim 15,
wherein the memory element layer includes a magnetic tunnel junction that includes a free magnetization layer, a tunnel barrier layer, and a fixed magnetization layer.
